(19) United States
(12) Patent Application Publication
(10) Pub. No.: US 2013/0014796 A1
(43) Pub. Date: Jan. 17, 2013

(54) THERMOELECTRIC ELEMENT AND THERMOELECTRIC MODULE

(71) Applicant: Kenichi Tajima, Kirishimi-shi (JP)

(72) Inventor: Kenichi Tajima, Kirishimi-shi (JP)

(73) Assignee: KYOCERA CORPORATION, Kyoto-shi, Kyoto (JP)

(21) Appl. No.: 13/580,559

(22) PCT Filed: Feb. 28, 2011
(86) PCT No.: PCT/JP2011/054485

§ 371 Date: Oct. 2, 2012

(30) Foreign Application Priority Data
Mar. 25, 2010 (JP) 2010070396

(51) Int. Cl. H01L 35/32

(52) U.S. Cl. 136/203

(57) ABSTRACT

There are provided a thermoelectric element and a thermoelectric module that are manufacturable at low cost, suffer little from deterioration in thermoelectric characteristics even after a long period of use, and excel in durability. A thermoelectric element of the invention includes a columnar thermoelectric element main body, an insulating layer disposed on a periphery of the thermoelectric element main body, and a metal layer disposed on an end face of the thermoelectric element main body, the metal layer covering an end face of the insulating layer. Accordingly, a reaction with a solder is prevented and high thermoelectric characteristics is maintained even during a long period of use.

### TECHNICAL FIELD

The present invention relates to a thermoelectric element and a thermoelectric module that are manufacturable at low cost and excel in durability, which are suitable for use in, for example, cooling of a heat-generating element such as a semiconductor.

### BACKGROUND ART

Thermoelectric elements that utilize the Peltier effect have hitherto been used as thermoelectric modules for application purposes such as temperature control in laser diode and cooling operation in equipment such as a constant-temperature bath and a refrigerator, and have recently been finding automotive applications involving air-conditioning control and seat temperature control.

For example, a thermoelectric module for cooling purposes includes a pair of P-type and N-type thermoelectric elements formed of thermoelectric materials made of A₂B₃-type crystal (A represents Bi and/or Sb, and B represents Te and/or Se) having excellent cooling characteristics. For example, as exemplary of thermoelectric materials having outstanding performance capability, a thermoelectric material made of a solid solution of Bi₂Te₃ (bismuth telluride) and Sb₂Te₃ (antimony telluride) is used for the P-type thermoelectric element, and a thermoelectric material made of a solid solution of Bi₂Te₃ (bismuth telluride) and Bi₂Se₃ (bismuth selenide) is used for the N-type thermoelectric element.

The thermoelectric module is constructed by arranging the P-type thermoelectric element and the N-type thermoelectric element made of such thermoelectric materials, which are electrically connected in series with each other, between two support substrates provided in a pair each having a wiring conductor (copper electrode) formed on its surface, and connecting the P-type and N-type thermoelectric elements with the wiring conductor by means of soldering.

It is known that such thermoelectric element and thermoelectric module can be obtained at low cost by a method involving a step of applying a resin coating to a rod-shaped thermoelectric material, a step of cutting the thermoelectric material, and a step of plating the plane of section with Ni (refer to Patent Literature 1)

### CITATION LIST

### Patent Literature

Patent Literature 1: Japanese Unexamined Patent Publication JP-A 11-68174 (1999)

### SUMMARY OF INVENTION

### Technical Problem

In recent years, however, reduction in cost and long-term durability have come to be increasingly demanded of thermoelectric modules. Decrease in durability may be attributed to a reaction between a thermoelectric element and solder used for bonding of the thermoelectric element. In the thermoelectric element obtained in Patent literature 1, the thermoelectric element has its side surfaces coated with resin, wherefore a reaction with solder via this resin-coated side surfaces can be prevented. However, merely a layer of metal such as Ni is disposed on the end face of the thermoelectric element main body obtained by cutting the rod-shaped thermoelectric material. In this case, since a gap remains between the resin layer and the thermoelectric element, it becomes impossible to prevent a reaction with solder with perfection due to the presence of the gap. This results in deterioration in thermoelectric characteristics during a long period of use.

Accordingly, an object of the invention is to provide a thermoelectric element and a thermoelectric module that are manufacturable at low cost, suffer little from deterioration in thermoelectric characteristics even after a long period of use, and excel in durability.

### Solution To Problem

The invention provides a thermoelectric element including: a columnar thermoelectric element main body; an insulating layer disposed on a periphery of the thermoelectric element main body; and a metal layer disposed on an end face of the thermoelectric element main body, the metal layer extending from the end face of the thermoelectric element main body to an end face of the insulating layer.

Moreover, the invention provides a thermoelectric module including: a pair of support substrates arranged face-to-face with each other; wiring conductors disposed on one main surface and one main surface of the pair of support substrates which confront each other; and a plurality of the above-described thermoelectric elements, the plurality of the above-described thermoelectric elements being arranged between the one main surfaces confronting each other.

### Advantageous Effect Of Invention

In the thermoelectric element of the invention, since the metal layer disposed on the end face of the thermoelectric element main body extends to cover the end face of the insulating layer disposed on the periphery of the thermoelectric element main body, it is possible to achieve improvement in thermoelectric characteristics. There are two reasons for this. First, the area of the metal layer which exhibits low thermal resistance is increased, thereby mitigating the influence exerted by the insulating layer which exhibits high thermal resistance, with consequent attainment of higher heat flux. Second, since the metal layer covers a gap between the insulating layer and the thermoelectric element main body, it is possible to prevent solder from flowing into the gap, and thereby suppress deterioration in thermoelectric characteristics resulting from a reaction between the solder and the thermoelectric element during a long period of use.

Moreover, in the thermoelectric module employing the above-described thermoelectric element, since a reaction between solder and the thermoelectric element main body can be prevented, it is possible to attain higher heat flux, and thereby provide even greater thermoelectric characteristics and excellent reliability.

### BRIEF DESCRIPTION OF THE DRAWINGS

FIG. 1 is a sectional view showing a thermoelectric element according to one embodiment of the invention.

FIG. 2 is a sectional view showing a thermoelectric element according to another embodiment of the invention.

FIG. 3 is a sectional view showing a thermoelectric element according to another embodiment of the invention.

FIG. 4 is a sectional view showing a thermoelectric element according to another embodiment of the invention.

FIG. 5 is a sectional view showing a thermoelectric module according to one embodiment of the invention; and

FIG. 6 is an exploded perspective view showing the thermoelectric module according to one embodiment of the invention.

### DESCRIPTION OF EMBODIMENTS

Hereinafter, embodiments of the thermoelectric element pursuant to the invention will be described with reference to the drawings.

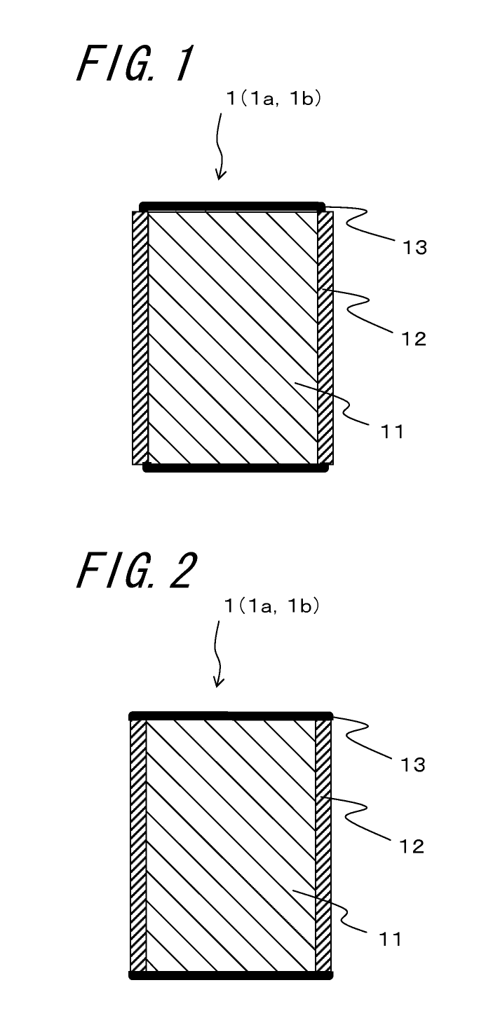

FIG. 1 is a sectional view showing a thermoelectric element according to one embodiment of the invention. The thermoelectric element 1 (1a, 1b) shown in FIG. 1 includes a columnar thermoelectric element main body 11, an insulating layer 12 disposed on a periphery of the thermoelectric element main body 11, and a metal layer 13 disposed on an end face of the thermoelectric element main body 11. The metal layer 13 extends from the end face of the thermoelectric element main body 11 to an end face of the insulating layer 12.

For example, the thermoelectric element main body 11 is formed, in the shape of a column, of a thermoelectric material made of A₂B₃-type crystal (A represents Bi and/or Sb, and B represents Te and/or Se), more preferably a bismuth (Bi), tellurium (Te)-based thermoelectric material. More specifically, in the N-type thermoelectric element 1a, for example, the thermoelectric element main body 11 is formed of a thermoelectric material made of a solid solution of Bi₂Te₃ (bismuth telluride) and Bi₂Se₃ (bismuth selenide). On the other hand, in the P-type thermoelectric element 1b, for example, the thermoelectric element main body 11 is formed of a thermoelectric material made of a solid solution of Bi₂Te₃ (bismuth telluride) and Sb₂Te₃ (antimony telluride). Exemplary of such a thermoelectric material are an ingot material obtained by re-solidifying a raw material which had once been molten, a sintered material obtained by pulverizing alloy powder and sintering pulverized alloy powder by hot-pressing or otherwise, and a single crystal material obtained by unidirectionally solidifying a raw material according to the Bridgman method, for example. The use of a single crystal material is particularly desirable with consideration given to its high performance capability. While the thermoelectric element main body 11 may be given either a cylindrical shape or a quadrangular prismatic shape, or a polygonal prismatic shape, in the interest of imparting thickness uniformity to the insulating layer 12 as will hereafter be described, the thermoelectric element main body 11 is preferably shaped in a cylindrical column. In the case of adopting a cylindrical column, the thermoelectric element main body 11 is configured to have a diameter in a range of e.g. 1 mm to 3 mm, and a length in a range of e.g. 0.3 mm to 5 mm.

On the periphery of the thermoelectric element main body 11 is disposed the insulating layer 12. The insulating layer 12 is formed, for example, by etching the surface of the thermoelectric material constituting the thermoelectric element main body 11 and whereafter covering the etched surface with a covering material for forming the insulating layer 12. In the etching process, nitric acid is desirable for use from the viewpoint of adhesion between the thermoelectric element main body 11 and the covering material. Moreover, there are several techniques for application of the covering material, namely spraying, dipping, brush coating, vapor deposition, and so forth. Among them, dipping is desirable for use from the cost and mass-production standpoint.

As the covering material for forming the insulating layer 12, for example, it is possible to use resin which is greater in insulation than the thermoelectric material. More specifically, epoxy resin, polyimide resin, acrylic resin, or the like is desirable for use with consideration given to their capability of lessening the load placed on the thermoelectric material constituting the thermoelectric element main body 11 during machining operation. The use of epoxy resin is particularly desirable in view of cost, electrical insulation, prevention of moisture-induced corrosion, and formation of the metal layer 13 as will hereafter be described. While the insulating layer 12 can be configured to have a thickness in a range of e.g. 5 μm to 50 μm, preferably in a range of e.g. 10 μm to 20 μm, there is no particular limitation to the thickness.

On the end face of the thermoelectric element main body 11 is disposed the metal layer 13 so as to extend from the end face of the thermoelectric element main body 11 to the end face of the insulating layer 12.

By disposing the metal layer 13 so as to extend from the end face of the thermoelectric element main body 11 to the end face of the insulating layer 12, it is possible to increase the area of the metal layer 13 which exhibits low thermal resistance, and thereby mitigate the influence exerted by the insulating layer 12 which exhibits high thermal resistance and thus attain higher heat flux. Moreover, since the metal layer 13 covers a gap between the insulating layer 12 and the thermoelectric element main body 11, it is possible to prevent solder from flowing into the gap, and thereby suppress deterioration in thermoelectric characteristics resulting from a reaction between the solder and the thermoelectric element during a long period of use.

As shown in FIG. 2, it is preferable that the metal layer 13 is disposed on the end face of the thermoelectric element main body 11, as well as on the end face of the insulating layer 12, so as to cover the entire end face of the insulating layer 12. In the case where the end face of the insulating layer 12 is wholly covered with the metal layer 13, the solder, even if it has a high fluidity, is restrained from flowing into the gap between the insulating layer 12 and the thermoelectric element main body 11, and eventually comes around the outer periphery (side surfaces) of the insulating layer 12. That is, the flow of the solder into the gap is blocked, wherefore deterioration in thermoelectric characteristics resulting from a reaction between the solder and the thermoelectric element during a long period of use can be suppressed.

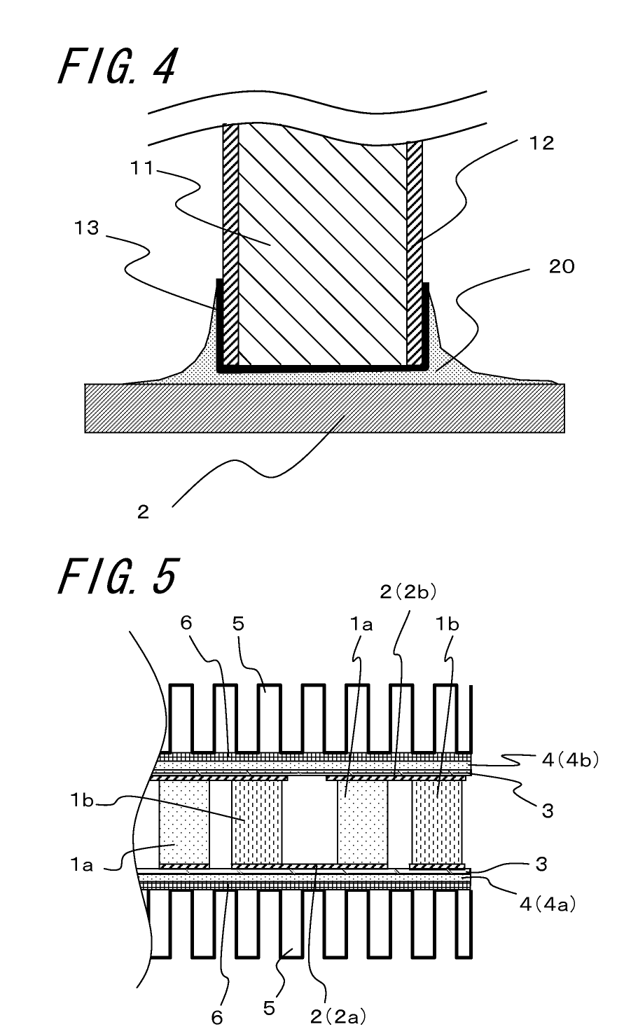

For example, a plating layer formed by means of electrolytic plating, electroless plating, or otherwise can be used for the metal layer 13. In this case, the plating layer is composed of a Ni layer disposed in contact with the end faces of the thermoelectric element main body 11 and the insulating layer 12, and also, preferably, a Sn layer or Au layer formed on the Ni layer. By disposing the Sn layer or Au layer on the Ni layer, it is possible to enhance the strength of adhesion to a bonding material 20 such as solder as shown in FIG. 4. While the metal layer 13 can be configured to have a thickness in a range of e.g. 5 μm to 20 μm in so far as it is formed of the plating layer, there is no particular limitation to the thickness.

Moreover, the metal layer 13 can be formed by sputtering or thermal spraying instead of plating. In the case of adopting sputtering, the metal layer 13 is made of a material such as Ni or Pd with a thickness in a range of e.g. 0.1 μm to 3 μm. In the case of adopting thermal spraying, the metal layer 13 is made of a material such as Ni or Co with a thickness in a range of e.g. 1 μm to 20 μm.

While the metal layer 13 can be formed as a layer formed by sputtering or thermal spraying as above described instead of a plating layer, the metal layer 13 is preferably a plating layer which can be formed through electric or chemical treatment. The metal layer 13 in the form of a plating layer will be excellent in adhesion to the thermoelectric element main body 11. Moreover, the hazard of damage to the insulating layer 12 ascribable to plating process is less than that ascribable to other processes (plasma damage in the sputtering, and metal-particle collision damage in the thermal spraying). Accordingly, both improvement in reliability and prevention of deterioration in thermoelectric characteristics can be achieved. Further, where the metal layer 13 is a plating layer, it is desirable to use epoxy resin with a high hardness for the insulating layer 12. In this case, in contrast to the case of using resin with a low hardness, it is possible to reduce the hazard of damage to the insulating layer 12, and thereby form a plating layer on the end face of the insulating layer 12 formed on the periphery of the thermoelectric element main body 11 so as to extend from there and wrap around the end portion of the insulating layer 12 (around the outer periphery (side surface) near the end face) as will hereafter be described.

The electrolytic plating method is desirable for use in forming the metal layer 13 as a plating layer by means of plating. According to the electrolytic plating method, although the end face of the thermoelectric element main body 11 is preferentially formed with a plating film, presumably, by adjusting conditions for film formation to be fulfilled in electrolytic plating process, it is possible to grow a plating film so as to extend from the end face of the thermoelectric element main body 11 to the end face of the insulating layer 12. Thus, the end face of the insulating layer 12 is also formed with a plating film. It is particularly desirable to effect film formation while maintaining the rate of deposition at a high level. For example, it is desirable to set the current value at or above 20 A during electrolytic plating process to raise the deposition rate. In this way, a plating film adheres on to the thermoelectric element main body 11 at the initial stage of electrolytic plating process, and is then grown to extend over the end face of the insulating layer 12 under a high-deposition rate condition.

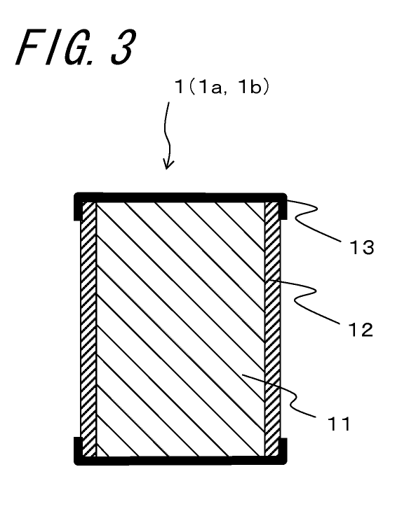

Moreover, as shown in FIG. 3, the metal layer 13 preferably extends over the end portion of the insulating layer 12, and more preferably extends over the entire perimeter of the end portion of the insulating layer 12. As employed herein the end portion refers to the outer periphery (side surface) near the end face.

Thus, the strength of adhesion between the metal layer 13 and the insulating layer 12 can be enhanced, and, as shown in FIG. 4, the bonding material (solder) for forming a thermoelectric module becomes capable of forming a fillet. This makes it possible to enhance the strength of adhesion between the thermoelectric element and the support substrate, and thereby achieve improvement in reliability. Although the intended effects can be attained in so far as the metal layer 13 extends to the end portion in part, in the interest of enhancement in strength, it is desirable to extend the metal layer 13 over the entire perimeter of the end portion. In order to obtain such effects, a spread width of the metal layer 13 is preferably in a range of e.g. 0.05 mm to 0.20 mm.

When used in automotive applications, the thermoelectric element may be operated in harsh environments, for example, it may be exposed to vibration for a long period of time, or may be set in motion after having been left standing in a high-temperature or low-temperature condition. In such a case, the end portion of the bonding material (solder) 20 is subjected to concentration of great stress. In this regard, as shown in FIG. 4, with the metal layer 13 extending over the entire perimeter of the end portion of the insulating layer 12, even if stress is concentrated on the end portion of the bonding material (solder) 20, neither the bonding material (solder) 20 nor the metal layer 13 will break. At this time, part of the insulating layer 12 falls off from the end portion of the bonding material (solder) 20, thereby allowing stress relaxation. Since some insulating layer 12 peels off at its interior, it never occurs that the thermoelectric element main body 11 is exposed. Accordingly, stress relaxation can be achieved exclusively without causing any damage to the thermoelectric element main body 11.

Moreover, it is preferable that the spread width of the metal layer 13 is uniform throughout the perimeter of the end portion of the insulating layer 12. As employed herein uniformity in spread width throughout the perimeter is construed as encompassing the variation of width falling within a tolerance of plus or minus 10%, and preferably plus or minus 5%, with respect to the mean. In so far as the spread width of the metal layer 13 is uniform throughout the perimeter of the end portion of the insulating layer 12, even if stress is developed in any direction when the thermoelectric element is mounted in a thermoelectric module, stress relaxation effect can be obtained.

Particularly, with the placement of the thermoelectric element, whose metal layer 13 extends over the entire perimeter of the end portion of the insulating layer 12, in a position along the outer periphery of a thermoelectric module that is most susceptible to stress, the thermoelectric module becomes capable of exhibiting a great stress relaxation effect and can thus be operated for a longer period of time with stability. Moreover, by designing each of the thermoelectric elements that are to be mounted in a thermoelectric module in a manner such that the spread width of the metal layer 13 is substantially uniform throughout the perimeter of the end portion of the insulating layer 12, the thermoelectric module becomes capable of exhibiting maximum stress relaxation effect and can thus be operated for a longer period of time with stability.

In order to configure the metal layer to have such an extension, it is advisable to prolong the time required for plating film formation so that the resultant plating layer has a thickness of greater than or equal to one-half of the thickness of the insulating layer 12, more specifically a thickness of greater than or equal to 5 μm, and preferably a thickness in a range of 10 μm or more and 20 μm or less. Such a range in thickness is desirable in enhancing the strength of the metal layer 13 coated on the end face of the insulating layer 12, wherefore its fulfillment eliminates the possibility of lowering the intended effect due to breakage resulting from a long period of use.

Moreover, at least a part of the insulating layer 12 that is covered with the metal layer 13 is preferably roughened in its surface. In this case, the adhesion between the metal layer 13 and the insulating layer 12 can be enhanced by an anchor effect. The surface roughening is performed to such an extent as to obtain a surface roughness Ra in a range of e.g. 2 μm to 8 μm for effect. To obtain such a roughened surface, a few ways can be adopted, i.e. performing blast finishing on the surface; grinding the surface and whereafter subjecting it to heat treatment at a temperature of higher than or equal to 200° C.; and washing the surface with water and whereafter subjecting it to etching using an acidic aqueous solution such as dilute hydrochloric acid or an alkaline aqueous solution such as aqueous sodium hydroxide.

The thermoelectric element 1 thus far described is built under the concept that it includes N-type and P-type thermoelectric elements. The N-type thermoelectric element and the P-type thermoelectric element are formed of different thermoelectric materials. The N-type thermoelectric element and the P-type thermoelectric element, which are electrically connected in series with each other, are arranged between the main surfaces of a pair of support substrates, thereby constituting a thermoelectric module which will hereafter be described.

Hereinafter, embodiments of the thermoelectric module pursuant to the invention will be described with reference to the drawings.

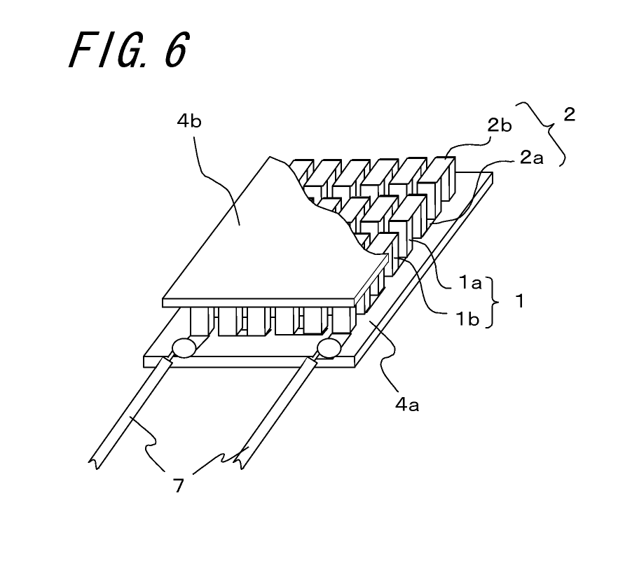

FIG. 5 is a sectional view showing a thermoelectric module according to one embodiment of the invention, and FIG. 6 is an exploded perspective view showing the thermoelectric module according to one embodiment of the invention.

The thermoelectric module shown in FIGS. 5 and 6 is configured to include the thermoelectric element 1 (N-type thermoelectric element 1a and P-type thermoelectric element 1b) shown in FIG. 1. More specifically, the thermoelectric module includes a pair of support substrates 4 (4a, 4b) arranged face-to-face with each other; wiring conductors 2 (2a, 2b) disposed on one main surface and one main surface of the pair of support substrates 4 (4a, 4b) which confront each other; and a plurality of the above-described thermoelectric elements 1 (N-type thermoelectric element 1a and P-type thermoelectric element 1b), the plurality of the above-described thermoelectric elements being arranged between the one main surfaces confronting each other.

The support substrate 4 (4a, 4b), which is made of a material such for example as Cu, Ag or Ag—Pd, is for example 40 to 50 mm long and 20 to 40 mm wide when viewed in plane, and has a thickness in a range of ca. 0.05 mm to 2 mm. Note that the support substrate 4 may be of a double-sided copper-clad laminate substrate made of alumina filler-containing epoxy resin. In another alternative, the support substrate 4 may be made of a ceramic material such as alumina or aluminum nitride. In this case, there is no need to provide an insulating layer 3 which will hereafter be described.

The wiring conductor 2 (2a, 2b), which is made of a material such for example as Cu, Ag or Ag—Pd, is configured to establish electrical series connection between the adjacent N-type thermoelectric element 1a and P-type thermoelectric element 1b.

Moreover, where the support substrate 4 (4a, 4b) is made of an electrically conducting material, with the aim of providing insulation between the support substrate 4 and the wiring conductor 2, the insulating layer 3 made of a material such for example as epoxy resin, polyimide resin, alumina, and aluminum nitride is disposed between the support substrate 4 (4a, 4b) and the wiring conductor 2 (2a, 2b).

Further, as shown in the figure, a heat exchanger 5 made of a material such for example as copper or aluminum is disposed on the other main surface of the support substrate 4 (4a, 4b), with a bonding member 6 such as Sn—Bi solder or Sn—Ag—Cu solder having high thermal conductivity lying between them.

In the thermoelectric module thus constructed, heat resulting from an endothermic or exothermic reaction occurring in the wiring conductor 2 (2a, 2b) is transmitted to the heat exchanger 5, so that the heat exchanger 5 effects cooling or heat radiation. At this time, by the passage of air through the heat exchanger 5 for air cooling, cooled or heated air is generated, thereby allowing a use as an air conditioner. Moreover, by placing the heat exchanger 5 directly in a heat-insulated space, a cooling-warming storage cabinet can be produced.

The thermoelectric module shown in FIGS. 5 and 6 thus far described can be produced in the following manner.

The first step is to bond the thermoelectric element 1 (N-type thermoelectric element 1a and P-type thermoelectric element 1b) shown in FIG. 1 and the support substrate 4 together.

More specifically, a solder paste or a bonding material made of a solder paste is applied to at least part of the wiring conductor 2a formed on the support substrate 4a, thereby forming a solder layer. As a method for the application, it is desirable to adopt screen printing using a metal mask or screen mesh from the cost and mass-production standpoint.

Then, the thermoelectric elements 1 are arranged on the surface of the wiring conductor 2a coated with the bonding material (solder). At this time, it is necessary to arrange two types of thermoelectric elements 1, namely the N-type thermoelectric element 1a and the P-type thermoelectric element 1b. Although the bonding can be conducted by any given technique in so far as it is heretofore known, as a matter of convenience and facilitation, it is desirable to adopt such a method that the N-type thermoelectric element 1a and the P-type thermoelectric element 1b are arrayed in a vibratory pallet method in which they are caused to vibrate separately so as to be fed to a jig having holes formed in an array, and an array of the elements is transferred onto the support substrate 4a.

Following the completion of arrangement of the thermoelectric elements 1 (the N-type thermoelectric element 1a and the P-type thermoelectric element 1b) on the support substrate 4a, the opposite support substrate 4b is placed on the top surfaces of the thermoelectric elements 1 (the N-type thermoelectric element 1a and the P-type thermoelectric element 1b).

More specifically, the support substrate 4b with the wiring conductor 2a, the surface of which is coated with solder, is soldered to the top surfaces of the thermoelectric elements 1 (the N-type thermoelectric element la and the P-type thermoelectric element 1b) by a heretofore known technique. Although the soldering can be conducted by any given technique, for example, application of heat by a reflow furnace or heater, where resin is used for the support substrate 20, it is desirable to perform heating while applying stress to both top and bottom sides from the viewpoint of enhancing the adhesion between the solder and the thermoelectric elements 1 (the N-type thermoelectric element 1a and the P-type thermoelectric element 1b).

Next, the heat exchanger 5 is mounted, via the bonding member 6, on the support substrate 4 (4a, 4b) thus attached to each side of the thermoelectric element 1. The heat exchanger 5 for use comes in varying shapes and materials for different application purposes. When used as an air conditioner whose main application is for cooling, the heat exchanger 5 is preferably constructed of a copper-made fin. Especially for air-cooling application, a fin in a corrugated form is desirable for use in the interest of increasing the area of a part which is exposed to air. Moreover, by using a heat exchanger having even greater heat-exchange capacity for the heat exchanger 5 at the heat-radiation side, it is possible to attain even higher heat-radiation performance, and thereby improve the cooling characteristics.

Lastly, a lead wire 7 for passing electric current through the wiring conductor 2 is disposed by bonding using soldering iron, laser, or the like. In this way, the thermoelectric module of the invention is obtained.

### Examples

Hereinafter, the invention will be described by way of examples in more detail.

To begin with, a Bi, Te, Se-made N-type thermoelectric material and a Bi, Sb, Te-made P-type thermoelectric material, which materials were obtained by once melting the above components and then re-solidifying them, were unidirectionally solidified according to the Bridgman method to prepare rod-like N-type and P-type thermoelectric materials which have a diameter of 1.8 mm. More specifically, the N-type thermoelectric material was made of a solid solution of Bi₂Te₃ (bismuth telluride) and Bi₂Se₃ (bismuth selenide), and the P-type thermoelectric material was made of a solid solution of Bi₂Te₃ (bismuth telluride) and Sb₂Te₃ (antimony telluride).

After the surface of each of the rod-like N-type and P-type thermoelectric materials was etched with nitric acid, a 30 μm-thick covering material for forming the insulating layer was coated on the periphery of each of the thermoelectric materials. The covering material is a solder resist made of epoxy resin. The dipping technique was used as a way to apply a coating of the covering material.

Next, each of the rod-like N-type and P-type thermoelectric materials covered with the covering material was cut in a thickness of 1.6 mm by a wire saw to obtain an N-type thermoelectric element (cylindrical body made of N-type thermoelectric material) and a P-type thermoelectric element (cylindrical body made of P-type thermoelectric material). In each of the N-type thermoelectric element and the P-type thermoelectric element thus obtained, a nickel layer was formed on the plane of section thereof by means of electrolytic plating. At this time, three different samples were prepared under varying conditions as to nickel layer-forming region.

More specifically, there were prepared three samples, namely Sample 1 (Comparative Example) in which the end face of the epoxy resin-made insulating layer was not covered with the nickel layer, Sample 2 (Example) in which the end face of the epoxy resin-made insulating layer was covered with the nickel layer, and Sample 3 (Example) in which the nickel layer was so formed as to extend over the end portion beyond the end face of the epoxy resin-made insulating layer (over the outer periphery near the end face).

Then, there was prepared a copper-made support substrate which had a 80 μm-thick epoxy resin-made insulating layer formed on its one main surface, and also had a 105 ƒm-thick wiring conductor formed on the insulating layer (40 mm in length, 40 mm in width, and 105 pm in thickness). Moreover, a 95Sn-5Sb solder paste was applied on to the wiring conductor with use of a metal mask.

Further, on the solder paste were arranged 127 N-type thermoelectric elements and 127 P-type thermoelectric elements in a manner such that the N-type thermoelectric element and the P-type thermoelectric element were electrically connected in series with each other by parts feeder. The N-type and P-type thermoelectric elements thus arranged were sandwiched between two support substrates, and subjected to heating process in a reflow furnace under stress applied to both top and bottom sides, thereby bonding the wiring conductor and the thermoelectric element together through the solder. Lastly, the heat exchanger (copper-made fin) was attached to the support substrate via the bonding member. In this way, a thermoelectric module as shown in FIG. 5 was obtained.

Next, there were prepared 50 thermoelectric modules constructed of the thermoelectric elements of different samples. In conducting performance evaluations on the prepared thermoelectric modules in terms of cooling capability indicative of thermoelectric characteristics, an electric current (Imax: 6A) was applied to measure the difference in temperature between the upper and lower heat exchangers. Following the completion of 10000 cycles of continuous current test based on ON-OFF alternate operation at intervals of five minutes, the thermoelectric modules were placed under a temperature of −50° C. and a temperature of 100° C. alternately for 15 minutes, respectively, which constituted one cycle of operation. The thermoelectric modules were subjected to 1000 cycles of this temperature cycling test.

The rates of change in cooling capability of the thermoelectric modules were measured through observation of the contrast between before and after the current test and the temperature cycling test, and the values were averaged to derive a mean. The result showed that the rate of change of the thermoelectric module constructed of the thermoelectric element of Sample 1 was 25%; the rate of change of the thermoelectric module constructed of the thermoelectric element of Sample 2 was 3%; and the rate of change of the thermoelectric module constructed of the thermoelectric element of Sample 3 was 1%.

As will be understood from the result, in contrast to Sample 1 based on the construction of conventional design, Samples 2 and 3 implemented as examples of the invention exhibit a low decrease rate of cooling temperature and are thus capable of providing excellent thermoelectric characteristics.

### REFERENCE SIGNS LIST

1: Thermoelectric element

1a: N-type thermoelectric element

1b: P-type thermoelectric element

11: Thermoelectric element main body

12: Insulating layer

13: Metal layer

14: Metal layer

15: Protrusion

2, 2a, 2b: Wiring conductor

3: Insulating layer

4, 4a, 4b: Support substrate

5: Heat exchanger

6: Bonding member

7: Lead wire

20: Bonding material (solder)

1. A thermoelectric element, comprising:
a columnar thermoelectric element main body;
an insulating layer disposed on a periphery of the thermoelectric element main body; and
a metal layer disposed on an end face of the thermoelectric element main body, the metal layer extending from the end face of the thermoelectric element main body to an end face of the insulating layer.

2. The thermoelectric element according to claim 1, wherein the metal layer covers the end face of the insulating layer.

3. The thermoelectric element according to claim 1, wherein the metal layer is a plating layer.

4. The thermoelectric element according to claim 1,
wherein the insulating layer contains epoxy resin as a main constituent.

5. The thermoelectric element according to claim 1,
wherein the metal layer extends to an end portion of the insulating layer.

6. The thermoelectric element according to claim 5,
wherein the metal layer extends over an entire perimeter of the end portion of the insulating layer.

7. The thermoelectric element according to claim 6,
wherein a spread width of the metal layer is uniform throughout the perimeter of the end portion of the insulating layer.

8. The thermoelectric element according to claim 1,
wherein the metal layer has a thickness of greater than or equal to one-half of a thickness of the insulating layer.

9. The thermoelectric element according to claim 1,
wherein at least a part of the insulating layer that is covered with the metal layer is roughened in its surface.

10. A thermoelectric module, comprising:
a pair of support substrates arranged face-to-face with each other;
wiring conductors disposed on one main surface and one main surface of the pair of support substrates which confront each other; and
a plurality of the thermoelectric elements according to claim 1, the plurality of thermoelectric elements being arranged between the one main surfaces confronting each other.
